(19) United States
(12) Patent Application Publication
(10) Pub. No.: US 2017/0141070 A1
(43) Pub. Date: May 18, 2017

(54) Clamping Assembly Having A Spring System

(71) Applicant: SIEMENS AKTIENGESELLSCHAFT, MUENCHEN (DE)

(72) Inventors: HOLGER SIEGMUND BREHM, ERLANGEN (DE); MATTHIAS BOEHM, NEUENDETTELSAU (DE); DANIEL SCHMITT, NUERNBERG (DE)

(21) Appl. No.: 15/323,496

(22) PCT Filed: Jul. 3, 2014
(86) PCT No.: PCT/EP2014/064179

§ 371 Date: Jan. 3, 2017

(51) Int. Cl. H01L 23/00; H01L 25/18; H02M 3/158; H01L 23/367

(52) U.S. Cl. CPC H01L 24/72; H01L 23/367; H01L 25/18; H02M 3/158

(57) ABSTRACT

A clamping assembly includes a configuration of mechanically clamped components that lie on top of one another to form a stack, a spring system and a clamping device for generating a mechanical compressive force onto the configuration of the components. The spring system is a spring plate formed by a multiplicity of plate spring elements that are disposed adjacent each other and are connected to each other. A sub-module of a converter includes at least one series circuit of power semiconductor switching units and an energy storage device connected in parallel therewith, in which the series circuit of the power semiconductor switching units is provided as the clamping device.

The invention relates to a clamping assembly having an arrangement of mechanically clamped components that lie one on top of the other so as to form a stack, said clamping assembly comprising a spring system and a clamping device for generating a mechanical compressive force on the arrangement of the components.

Such a clamping assembly is used by way of example in high voltage technology. In the case of high voltage technology, semi-conductor components in particular are clamped one to the other in order to achieve the best possible electrical contact between said components.

The known clamping assemblies are mostly clamped by way of mechanical elements, by way of example suitable threaded systems. The compressive force is transmitted to the arrangement of the components mostly in a spot-by-spot manner by way of one or multiple screw elements and said force is subsequently distributed over a large area by way of pressure pieces so that the components are compressed in the clamping assembly.

The article “4.5 kV Press Pack I=Designed for Ruggedness and Reliability” by S. Eicher et al., IAS Seattle 2004 discloses an IGBT module (a so-called press pack module) that comprises IGBT chip units that are arranged in parallel and are housed in a common housing. The housing comprises an upper and lower conductive plate that extends over multiple chip units and transmit the mechanical force, which is generated by a common clamping device, on to the chip units. Each chip unit forms an arrangement of components that lie one above the other so as to form a stack. Each of the arrangements that form the chip unit is allocated an individual plate spring so that the force can be transmitted to the IGBT chips in each case by means of the individual plate spring. However, the pressure is distributed on the compressed areas of the individual chip units by means of the respective plate spring in a relatively non-homogenous manner.

However, as the area of the compressed components increases, it becomes more important that the compressive force is distributed in a homogenous manner. In addition, thin and brittle components are used, such as by way of example semi-conductor chips, and it is vitally important that the compressive force is distributed in a homogenous manner. Inhomogeneity can lead in such cases to the components becoming damaged and failing.

The object of the invention is therefore to propose a clamping assembly of the type mentioned above, wherein the compressive force is transmitted as homogenously as possible. The object is achieved in accordance with the invention by means of a clamping assembly, wherein the spring device is a spring plate that is formed by a multiplicity of mutually connected plate spring elements that are arranged adjacent one to the other.

The mutually connected plate spring elements of the arrangement in accordance with the invention transmit the compressive force that is exerted by means of the clamping device on the components of the arrangement in such a manner that the compressive force is distributed in a relatively homogenous manner over the surface of the components that is facing the spring plate. This effect is in particular irrespective of the size of the surface area of the surface of the components because the spring plate can expand in size accordingly, wherein it is also possible to scale the number of spring plate elements to correspond with the size of the surface area.

In an expedient manner, the spring plate elements are formed as conical annular shells that comprise an upper e inner edge and a lower outer edge, wherein the force is introduced along the axis of symmetry of the annular shell. The plate spring elements are connected one to the other at the lower outer edge in an expedient manner.

In accordance with a preferred embodiment of the invention, the clamping assembly comprises a pressure piece for transmitting the mechanical compressive force from the clamping device to the arrangement of components. The spring plate is arranged between the pressure piece and the components. It is of advantage if the spring plate faces the pressure piece with the upper inner edges of the plate spring elements. It is possible by way of the suitably shaped pressure piece, wherein the pressure piece can have by way of example a conical or trapezoidal shape to transmit the compressive force from the clamping device to the components in a particular homogenous manner over the surface area. In an expedient manner, the base surface of the pressure piece is tailored to suit the geometry of the arrangement.

It is preferred that the spring plate elements comprise different spring characteristics. The different spring characteristics of the plate spring elements render it possible to adapt the transmission of the compressive force to the respective requirement in a particular efficient manner.

It is particularly advantageous if at least one of the plate spring elements comprises degressive spring characteristic. In the case of a degressive spring characteristic, the plate spring element is compressed in an over-proportional manner to a force that is acting on e the plate spring element.

In accordance with a preferred embodiment of the invention, the arrangement comprises a further spring plate that is arranged between two components. It is possible by means of using the additional spring plate to further improve the homogeneity of the transmission of the compressive force. Furthermore, it is naturally feasible also to provide spring plates in the clamping assembly.

Some of the components can be by way of example electrical components, wherein an electrical contact between said components is produced by way of the compressed surfaces of the electrical components.

In accordance with an advantageous embodiment of the invention, the arrangement comprises a semi-conductor element, wherein the semi-conductor element comprises press pack semi-conductors that are arranged in parallel. The semi-conductor element is consequently formed from semi-conductor modules that are arranged one adjacent to the other. The semi-conductor modules form a parallel connection of electrical components. By way of example, the components can be IGBT semi-conductors, diodes or thyristor elements. The surface of such semi-conductor modules can comprise by way of example a diameter of 6 to 9 mm. The surface of components that is to be compressed can be between 400 and 1000 cm².

For the purpose of cooling the semi-conductor elements, the arrangement further comprises in an advantageous manner at least one cooling plate that is embodied from a conductive material, wherein the at least one cooling plate is arranged lying on the semi-conductor element so that an e electrical contact is produced between the semi-conductor element and the cooling plate. The cooling pate is used to dissipate the heat that is produced in the semi-conductor element. This heat is produced in particular as a result of the on-state resistance of the semi-conductor element. In an expedient manner, the cooling plate is embodied from a thermal conductive preferably efficient heat-conductive material, such as by way of example metal or a metal alloy.

The arrangement can also comprise multiple semi-conductor elements, wherein each of the semi-conductor elements is allocated at least one cooling plate and the semi-conductor elements form an electrical series circuit.

It is particularly preferred if each semi-conductor element is allocated two cooling plates that are arranged on both sides of the semi-conductor element. In this manner, the heat can be dissipated on both sides of the semi-conductor element. Since the cooling plates are produced from a conductive material, the electrical contact between the semi-conductor elements can be produced by means of the cooling plates. In order to improve the transmission of the compressive force onto the semi-conductor elements, the arrangement can comprise an additional spring plate that is arranged between two cooling plates.

It is particularly preferred to provide a counter pressure piece that is arranged lying opposite the pressure piece, wherein an additional spring plate is arranged between the counter pressure piece and the components. The additional spring plate can be arranged in such a manner that the plate spring elements of the additional spring plate are orientated in an opposite direction to that of the spring plate.

Moreover, the invention relates to a sub-module of a convertor comprising at least one series circuit of power semi-conductor switching units that comprise in each case a power semi-conductor that can be switched on and off with an identical through-flow direction, and said power semi-conductor switching units are in each case conductive in the opposite direction to the said forward conduction direction and said convertor further comprising an energy storage device that is arranged in a parallel connection thereto. Such a sub-module is known by way of example from DE 101 030 31 A1.

Based on the known sub-module, a further object of the invention is to provide a sub-module of the above mentioned type that is susceptible as little as possible to failure.

The object is achieved in accordance with the invention by means of a generic type sub-module, wherein the series circuit of the power semi-conductor switching units is achieved in a previously described clamping device. By virtue of compressing the power semi-conductor switching units by means of the spring plate, it is possible to reduce the risk of damage occurring and consequently reduce the risk of the semi-conductor failing as a result of inhomogenous pressure distribution.

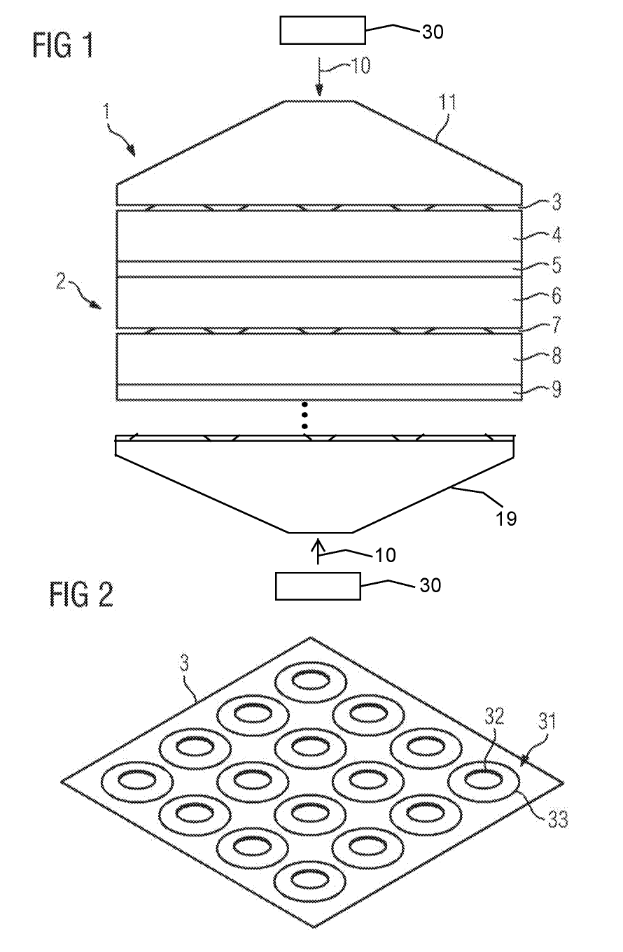

The invention is further explained hereinunder with reference to exemplary embodiments illustrated FIGS. 1-5.

FIG. 1 illustrates schematic lateral cross-sectional view of an exemplary embodiment of a clamping assembly in accordance with the invention,

FIG. 2 illustrates a perspective view of a spring plate of the clamping assembly shown in FIG. 1,

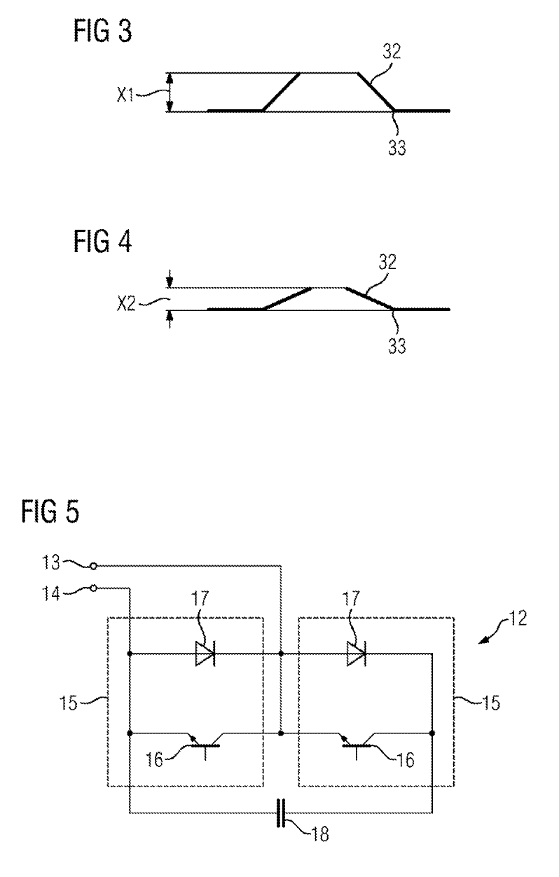

FIG. 3 illustrates a schematic lateral view of a plate spring element 31 shown in FIGS. 1 and 2,

FIG. 4 illustrates a lateral view of the plate spring element 31 of FIGS. 1 to 3 in a loaded position,

FIG. 5 illustrates a schematic view of an exemplary embodiment of a sub-module in accordance with the invention.

In detail, FIG. 1 illustrates an exemplary embodiment of a clamping assembly in accordance with the invention. The clamping assembly 1 comprises an arrangement 2 of components 3, 4, 5, 6, 7, 8 and 9. The components 3-9 are arranged one above the other so as to form a stack. The components 3-9 form a column-type arrangement 2. The arrangement 2 of the components is mechanically clamped by means of a clamping device that is not graphically illustrated in FIG. 1, wherein a compressive force acts on the arrangement 2, said force being identified by means of the arrow 10 in FIG. 1. The compressive force in the exemplary embodiment illustrated in FIG. 1 can amount to 10-12 t*g. A trapezoidal-type pressure piece 11 transmits the force from the clamping device to the arrangement. In detail, the arrangement comprises a first spring plate 3, a first cooling plate 4, a first semi-conductor element 5, a second cooling plate 6, a second spring plate 7, a third cooling plate 8 and a second semi-conductor element 9. Moreover, the arrangement 2 comprises further components that are arranged in FIG. 1 below the second semi-conductor element 9 but are not graphically illustrated in FIG. 1. The entire arrangement 2 is also mechanically clamped by means of a counter pressure piece that is not graphically illustrated in FIG. 1. However, it is provided in the present example to embody the clamping assembly according to a mirror-image of the illustrated upper half of the arrangement 2.

FIG. 2 illustrates a perspective view of the spring plate 3 shown in FIG. 1. In accordance with the exemplary embodiment of the clamping assembly 1 illustrated in FIG. 1, the spring plates 3 and 7 are embodied in an identical manner. The spring plate 3 comprises sixteen plate spring elements 31, wherein the plate spring elements 31 in accordance with the exemplary embodiment illustrated in FIG. 2 are all constructed in a similar manner. Each of the plate spring elements 31 comprises an upper inner edge 32 and a lower outer edge 33. The plate spring elements 31 are connected one to the other at their lower outer edges 33 so that they form the spring plate 3. In the exemplary embodiment illustrated in FIG. 2, the base surface of the spring plate is square. However, it is expedient to tailor the base surface to suit the base surface of the arrangement 2. This can be by way of example also rectangular or circular in shape. The plate spring elements 31 of the spring plate 3 comprise different spring characteristics in the event that it is expedient for the application of the clamping assembly 1. By way of example, the twelve plate spring elements 31 on the edge of the spring plate 3 comprise a different spring characteristic to the four other plate spring elements 31.

The behavior of one of the plate spring elements 31 when loaded by force is further explained in FIGS. 3 and 4.

FIG. 3 illustrates the plate spring element 31 in a non-loaded state, in other words if a force from the clamping device is not being transmitted to the spring plate 3. The distance between the lower outer edge 33 and the upper inner edge 32 of the plate spring element 31 is identified in this non-loaded state in FIG. 3 by xl.

It is evident in FIG. 4 that in a loaded state, the distance between the upper inner edge 32 and the lower outer edge 33 reduces. The reduced distance is identified in FIG. 4 by x2. The dependency of the difference between the distances x1-x2 upon the loading compressive force on the plate spring element 31 is described as a spring characteristic.

FIG. 5 illustrates an exemplary embodiment of a sub-module 12 in accordance with the invention. The sub-module 12 is embodied with two poles, wherein the poles or terminals of the sub-module 12 are identified in FIG. 5 by the reference numerals 13 and 14. The sub-module 12 forms a part of a converter that is not graphically illustrated, wherein a plurality of sub-modules that are constructed in an identical manner to the sub-module 12 are connected in series. The sub-module 12 comprises a series circuit of power semi-conductor switching units 15, wherein each of the two power semi-conductor switching units 15 comprises a power semi-conductor switch 16, which can be switched both on and also off, and a diode 17 that is connected thereto in parallel in an inverse manner. The sub-module 12 further comprises a storage capacitor 18 that is arranged in parallel with the series circuit of the power semi-conductor switches 15. The series circuit of the power semi-conductor switching units 15 is constructed in the form of a clamping assembly 1 illustrated in FIGS. 1 to 4.

### LIST OF REFERENCE NUMERALS

1 Clamping assembly

2 Arrangement

3 Spring plate

4, 6, 8 Cooling plate

5, 9 Semi-conductor element

10 Arrow

11 Pressure piece

12 Sub-module

13, 14 Terminal

15 Power semi-conductor switching unit

16 Power semi-conductor

17 Diode

18 Energy storage device

31 Plate spring element

32 Upper inner edge

33 Lower outer edge

1-12. (canceled)

13. A clamping assembly, comprising:
a configuration of mechanically clamped components lying on top of one other to form a stack;
a clamping device for generating a mechanical compressive force onto said configuration of said components; and
a spring system constructed as a spring plate formed by a multiplicity of mutually connected and mutually adjacent plate spring elements.

14. The clamping assembly according to claim 13, which further comprises a pressure piece for transmitting the mechanical compressive force from said clamping device to said the configuration, said spring plate being disposed between said pressure piece and said components.

15. The clamping assembly according to claim 13, wherein said plate spring elements have different spring characteristics.

16. The clamping assembly according to claim 13, wherein at least one of said plate spring elements has a degressive spring characteristic.

17. The clamping assembly according to claim 13, wherein said configuration includes a further spring plate disposed between two of said components.

18. The clamping assembly according to claim 13, wherein said configuration includes a semiconductor element having press pack semiconductors disposed in parallel.

19. The clamping assembly according to claim 18, wherein said configuration includes at least one cooling plate formed of a conductive material, and said at least one cooling plate is disposed adjacent said semiconductor element to produce an electrical contact between said semiconductor element and said cooling plate.

20. The clamping assembly according to claim 19, wherein said semiconductor element is one of a plurality of semiconductor elements of said configuration, each of said semiconductor elements is associated with at least one cooling plate, and said semiconductor elements form an electrical series circuit.

21. The clamping assembly according to claim 20, wherein each of said semiconductor elements is associated with two cooling plates, and said cooling plates are each disposed on a respective side of a respective one of said semiconductor elements.

22. The clamping assembly according to claim 21, wherein said configuration includes an additional spring plate disposed between two cooling plates.

23. The clamping assembly according to claim 22, which further comprises a counter pressure piece disposed opposite said pressure piece, and an additional spring plate disposed between said counter pressure piece and said components.

24. A sub-module of a converter, the sub-module comprising:
at least one series circuit of power semiconductor switching units;
said power semiconductor switching units each including a power semiconductor configured to be switched on and off and configured to have an identical forward conduction direction;
said power semiconductor switching units each being conductive in a direction opposite to said forward conduction direction;
an energy storage device connected in parallel to said power semiconductor switching units; and
said series circuit of said power semiconductor units being implemented as a clamping device according to claim 13.
